(19) United States
(12) Patent Application Publication
(10) Pub. No.: US 2026/0208556 A1
(43) Pub. Date: Jul. 23, 2026

(54) SYSTEMS AND METHODS FOR MANAGING ENERGY IN A VEHICLE

(71) Applicant: GM GLOBAL TECHNOLOGY OPERATIONS LLC, Detroit, MI (US)

(72) Inventors: Yongjie Zhu, Troy, MI (US); Jun-mo Kang, Ann Arbor, MI (US); Chunhao J. Lee, Troy, MI (US); Su-Yang Shieh, Clawson, MI (US); Shobhit Gupta, Sterling Heights, MI (US); Wesley Gerard Zanardelli, Rochester, MI (US); Norman K. Bucknor, Troy, MI (US)

(73) Assignee: GM GLOBAL TECHNOLOGY OPERATIONS LLC, Detroit, MI (US)

(21) Appl. No.: 19/032,876

(22) Filed: Jan. 21, 2025

(51) Int. Cl. B60H 1/00; B60R 16/033; H01M 10/613; H01M 10/625; H01M 10/63; H01M 10/656

(52) U.S. Cl. CPC B60H 1/0073; B60H 1/00278; B60R 16/033; H01M 10/613; H01M 10/625; H01M 10/63; H01M 10/656; B60H 2001/00307; H01M 2220/20

(57) ABSTRACT

A battery temperature difference between a battery temperature and a desired battery temperature, a power electronics temperature difference between a power electronics temperature and a desired power electronics temperature, and a cabin temperature difference between a vehicle cabin temperature and a desired vehicle cabin temperature are calculated. A power tuning factor is generated to determine an amount of cooling power to apply to a refrigerant and an amount of heating power to apply to a battery coolant and a power electronics coolant. Individual valves are either opened or closed to enable heat exchange between one or more of the battery coolant, the power electronics coolant, the refrigerant, and ambient air outside the vehicle to eliminate the battery temperature difference, the power electronics temperature difference, and the cabin temperature difference using the amount of cooling power and the amount of heating power associated with the power tuning factor.

### INTRODUCTION

The technical field generally relates to vehicles, and more particularly relates to systems and methods for managing energy in a vehicle.

Electric and hybrid vehicles typically include a high voltage (HV) battery system, power electronics, and a vehicle cabin. Such vehicles rely on coolants and refrigerant to maintain the HV battery system, the power electronics and the vehicle cabin at desired temperatures. The HV battery system supplies the power needed to adjust the temperatures of the coolants and refrigerant to maintain the HV battery system, the power electronics and the vehicle cabin at the desired temperatures.

Accordingly, it is desirable to provide systems and methods for managing energy of a vehicle. Other desirable features and characteristics will become apparent from the subsequent detailed description and the appended claims, taken in conjunction with the accompanying drawings and the foregoing technical field and background.

### SUMMARY

An energy management system for a vehicle includes at least one processor and at least one memory communicatively coupled to the at least one processor. The at least one memory includes instructions that upon execution by the at least one processor, causes the at least one processor to: receive a battery temperature from a battery temperature sensor of a high voltage (HV) battery of the vehicle, the battery temperature of the HV battery being based a battery coolant temperature of a battery coolant; receive a power electronics temperature from a power electronics temperature sensor of power electronics of the vehicle, the power electronics temperature being based on a power electronics coolant temperature of a power electronics coolant; receive a vehicle cabin temperature from a cabin temperature sensor of a vehicle cabin, the vehicle cabin temperature being based on a refrigerant temperature of a refrigerant; calculate a battery temperature difference between the battery temperature and a desired battery temperature, a power electronics temperature difference between the power electronics temperature and a desired power electronics temperature, and a cabin temperature difference between the vehicle cabin temperature and a desired vehicle cabin temperature; generate a power tuning factor to determine an amount of cooling power to apply to the refrigerant and an amount of heating power to apply to the battery coolant and the power electronics coolant; and place each of a plurality of valves in one of an open position and a closed position to enable heat exchange between one or more of the battery coolant, the power electronics coolant, the refrigerant, and ambient air outside the vehicle to eliminate the battery temperature difference, the power electronics temperature difference, and the cabin temperature difference using the amount of cooling power and the amount of heating power associated with the power tuning factor.

In at least one embodiment, the at least one memory further includes instructions that upon execution by the at least one processor, causes the at least one processor to place a first valve of the plurality of valves in one of an open position and a closed position, wherein: the open position of the first valve merges the battery coolant with the power electronics coolant to generate a combined coolant, the battery temperature of the HV battery and the power electronics temperature of the power electronics is based on a combined coolant temperature of the combined coolant, and the closed position of the first valve separates the battery coolant from the power electronics coolant.

In at least one embodiment, the at least one memory further includes instructions that upon execution by the at least one processor, causes the at least one processor to place a second valve of the plurality of valves in one of an open position and a closed position, wherein: the open position of the second valve enables dissipation of heat from one of the power electronics coolant and the combined coolant to the ambient air outside of the vehicle, and the closed position of the second valve disables the dissipation of heat from the one of the power electronics coolant and the combined coolant to the ambient air.

In at least one embodiment, the at least one memory further includes instructions that upon execution by the at least one processor, causes the at least one processor to place a third valve of the plurality of valves in one of an open position and a closed position, wherein: the open position of the third valve enables heat transfer between the refrigerant and one of the battery coolant and the combined coolant, and the closed position disables the heat transfer between the refrigerant and the one of the battery coolant and the combined coolant.

In at least one embodiment, the at least one memory further includes instructions that upon execution by the at least one processor, causes the at least one processor to place a fourth valve of the plurality of valves in one of an open position and a closed position, wherein: the open position of the fourth valve enables dissipation of heat from the refrigerant to the ambient air outside of the vehicle, and the closed position disables the dissipation of heat from the refrigerant to the ambient air.

In at least one embodiment, the at least one memory further includes instructions that upon execution by the at least one processor, causes the at least one processor to place a fifth valve of the plurality of valves in one of an open position and a closed position, wherein: the open position of the fifth valve enables heat exchange between the air in the vehicle cabin and the refrigerant, and the closed position disables the heat exchange between the air in the vehicle cabin and the refrigerant.

In at least one embodiment, the at least one memory further includes instructions that upon execution by the at least one processor, causes the at least one processor to apply the amount of the heating power and the amount of the cooling power in accordance with the generated power tuning factor based on a relationship defined by a first cost function J1, the first cost function J1 being:

$$J 1 = {\sum }_{k = 1}^{N} ( {( {T}_{b} ( k ) - {T}_{b}^{des} )}^{2} + {( {T}_{p} ( k ) - {T}_{p}^{des} )}^{2} + {( {T}_{c} ( k ) - {T}_{c}^{des} )}^{2} + \text{?} ( {Q}_{HEAT}^{2} ( k ) + {Q}_{AC}^{2} ( k ) ) ,$$

wherein: T_{b} is the battery temperature,

$${T}_{b}^{des}$$

is the desired battery temperature, Tₚ is the power electronics temperature,

$${T}_{p}^{des}$$

is the desired power electronics temperature, Q_{HEAT} is the amount of the heating power, Q_{AC} is the amount of the cooling power, γ is the power tuning factor, and k is time steps 1 through N.

In at least one embodiment, the amount of the heating power is greater than or equal zero and the amount of the cooling power is greater than or equal zero.

In at least one embodiment, the at least one memory further includes instructions that upon execution by the at least one processor, causes the at least one processor to apply the amount of the heating power and the amount of the cooling power in accordance with the generated power tuning factor based on a relationship defined by a second cost function J2, the cost function J2 being:

$$J 2 = {\sum }_{k = 1}^{N} ( {{W}_{b} ( {T}_{b} ( k ) - {T}_{b}^{des} )}^{2} + {{W}_{p} ( {T}_{p} ( k ) - {T}_{p}^{des} )}^{2} + {{W}_{c} ( {T}_{c} ( k ) - {T}_{c}^{des} )}^{2} + \text{?} ( {Q}_{HEAT}^{2} ( k ) + {Q}_{AC}^{2} ( k ) ) ,$$

wherein: T_{b} is the battery temperature,

$${T}_{b}^{des}$$

is the desired battery temperature, Tₚ is the power electronics temperature,

$${T}_{p}^{des}$$

is the desired power electronics temperature, Q_{HEAT} is the amount of the heating power, Q_{AC} is the amount of the cooling power, γ is the power tuning factor, W_{b} is a battery temperature weighting factor, Wₚ is a power electronics temperature weighting factor, W_{c} is a cabin temperature weighting factor, and k is time steps/through N.

In at least one embodiment, the at least one memory further includes instructions that upon execution by the at least one processor, causes the at least one processor to: receive a state of charge (SOC) of the HV battery; and generate the power tuning factor based on the SOC of the HV battery.

A method of managing energy in a vehicle including: receiving, by the controller, a battery temperature from a battery temperature sensor of a high voltage (HV) battery of the vehicle, the battery temperature of the HV battery being based a battery coolant temperature of a battery coolant; receiving, by the controller, a power electronics temperature from a power electronics temperature sensor of power electronics of the vehicle, the power electronics temperature being based on a power electronics coolant temperature of a power electronics coolant; receiving, by the controller, a vehicle cabin temperature from a cabin temperature sensor of a vehicle cabin, the vehicle cabin temperature being based on a refrigerant temperature of a refrigerant; calculating, by the controller, a battery temperature difference between the battery temperature and a desired battery temperature, a power electronics temperature difference between the power electronics temperature and a desired power electronics temperature, and a cabin temperature difference between the vehicle cabin temperature and a desired vehicle cabin temperature; generating, by the controller, a power tuning factor to determine an amount of cooling power to apply to the refrigerant and an amount of heating power to apply to the battery coolant and the power electronics coolant; and placing, by the controller, each of a plurality of valves in one of an open position and a closed position to enable heat exchange between one or more of the battery coolant, the power electronics coolant, the refrigerant, and ambient air outside the vehicle to eliminate the battery temperature difference, the power electronics temperature difference, and the cabin temperature difference using the amount of cooling power and the amount of heating power associated with the power tuning factor.

In at least one embodiment, the method further includes placing, by the controller, a first valve of the plurality of valves in one of an open position and a closed position, wherein: the open position of the first valve merges the battery coolant with the power electronics coolant to generate a combined coolant, the battery temperature of the HV battery and the power electronics temperature of the power electronics is based on a combined coolant temperature of the combined coolant, and the closed position of the first valve separates the battery coolant from the power electronics coolant.

In at least one embodiment, the method further includes placing, by the controller, a second valve of the plurality of valves in one of an open position and a closed position, wherein: the open position of the second valve enables dissipation of heat from one of the power electronics coolant and the combined coolant to the ambient air outside of the vehicle, and the closed position of the second valve disables the dissipation of heat from the one of the power electronics coolant and the combined coolant to the ambient air.

In at least one embodiment, the method further includes placing, by the controller, a third valve of the plurality of valves in one of an open position and a closed position, wherein: the open position of the third valve enables heat transfer between the refrigerant and one of the battery coolant and the combined coolant, and the closed position disables the heat transfer between the refrigerant and the one of the battery coolant and the combined coolant.

In at least one embodiment, the method further includes placing, by the controller, a fourth valve of the plurality of valves in one of an open position and a closed position, wherein: the open position of the fourth valve enables dissipation of heat from the refrigerant to the ambient air outside of the vehicle, and the closed position disables the dissipation of heat from the refrigerant to the ambient air.

In at least one embodiment, the method further includes placing, by the controller, a fifth valve of the plurality of valves in one of an open position and a closed position, wherein: the open position of the fifth valve enables heat exchange between the air in the vehicle cabin and the refrigerant, and the closed position disables the heat exchange between the air in the vehicle cabin and the refrigerant.

In at least one embodiment, wherein the method further includes applying the amount of the heating power and the amount of the cooling power in accordance with the generated power tuning factor based on a relationship defined by a first cost function J1, the first cost function J1 being:

$$J 1 = {\sum }_{k = 1}^{N} ( {( {T}_{b} ( k ) - {T}_{b}^{des} )}^{2} + {( {T}_{p} ( k ) - {T}_{p}^{des} )}^{2} + {( {T}_{c} ( k ) - {T}_{c}^{des} )}^{2} + \text{?} ( {Q}_{HEAT}^{2} ( k ) + {Q}_{AC}^{2} ( k ) ) ,$$

wherein: T_{b} is the battery temperature,

$${T}_{b}^{des}$$

is the desire battery temperature, Tₚ is the power electronics temperature,

$${T}_{p}^{des}$$

is the desired power electronics temperature, Q_{HEAT} is the amount of the heating power, Q_{AC} is the amount of the cooling power, γ is the power tuning factor, and k is time steps/through N.

In at least one embodiment, the method further includes applying the amount of the heating power and the amount of the cooling power in accordance with the generated power tuning factor based on a relationship defined by a second cost function J2, the cost function J2 being:

$$J 2 = {\sum }_{k = 1}^{N} ( {{W}_{b} ( {T}_{b} ( k ) - {T}_{b}^{des} )}^{2} + {{W}_{p} ( {T}_{p} ( k ) - {T}_{p}^{des} )}^{2} + {{W}_{c} ( {T}_{c} ( k ) - {T}_{c}^{des} )}^{2} + \text{?} ( {Q}_{HEAT}^{2} ( k ) + {Q}_{AC}^{2} ( k ) ) ,$$

wherein: T_{b} is the battery temperature,

$${T}_{b}^{des}$$

is the desire battery temperature, Tₚ is the power electronics temperature,

$${T}_{p}^{des}$$

is the desired power electronics temperature, Q_{HEAT} is the amount of the heating power, Q_{AC} is the amount of the cooling power, γ is the power tuning factor, W_{b} is a battery temperature weighting factor, Wₚ is a power electronics temperature weighting factor, W_{c} is a cabin temperature weighting factor, and k is time steps 1 through N.

In at least one embodiment, the method further includes receiving a state of charge (SOC) of the HV battery; and generating the power tuning factor based on the SOC of the HV battery.

A vehicle including an energy management system includes at least one processor and at least one memory communicatively coupled to the at least one processor. The at least one memory includes instructions that upon execution by the at least one processor, causes the at least one processor to: receive a battery temperature from a battery temperature sensor of a high voltage (HV) battery of the vehicle, the battery temperature of the HV battery being based a battery coolant temperature of a battery coolant; receive a power electronics temperature from a power electronics temperature sensor of power electronics of the vehicle, the power electronics temperature being based on a power electronics coolant temperature of a power electronics coolant; receive a vehicle cabin temperature from a cabin temperature sensor of a vehicle cabin, the vehicle cabin temperature being based on a refrigerant temperature of a refrigerant; calculate a battery temperature difference between the battery temperature and a desired battery temperature, a power electronics temperature difference between the power electronics temperature and a desired power electronics temperature, and a cabin temperature difference between the vehicle cabin temperature and a desired vehicle cabin temperature; generate a power tuning factor to determine an amount of cooling power to apply to the refrigerant and an amount of heating power to apply to the battery coolant and the power electronics coolant; and place each of a plurality of valves in one of an open position and a closed position to enable heat exchange between one or more of the battery coolant, the power electronics coolant, the refrigerant, and ambient air outside the vehicle to eliminate the battery temperature difference, the power electronics temperature difference, and the cabin temperature difference using the amount of cooling power and the amount of heating power associated with the power tuning factor.

### BRIEF DESCRIPTION OF THE DRAWINGS

The exemplary embodiments will hereinafter be described in conjunction with the following drawing figures, wherein like numerals denote like elements, and wherein:

FIG. 1 is a functional block diagram of a vehicle including an energy management system in accordance with at least one embodiment;

FIG. 2 is a functional block diagram of a system configured to implement an energy management system in accordance with at least one embodiment;

FIG. 3 is a functional block diagram of a controller including an energy management system in accordance with at least one embodiment; and

FIG. 4 is a flowchart representation of an exemplary method of managing energy in a vehicle in accordance with at least one embodiment.

### DETAILED DESCRIPTION

The following detailed description is merely exemplary in nature and is not intended to limit the application and uses. Furthermore, there is no intention to be bound by any expressed or implied theory presented in the preceding technical field, background, brief summary or the following detailed description. As used herein, the term module refers to an application specific integrated circuit (ASIC), an electronic circuit, a processor (shared, dedicated, or group) and memory that executes one or more software or firmware programs, a combinational logic circuit, and/or other suitable components that provide the described functionality.

Embodiments of the present disclosure may be described herein in terms of functional and/or logical block components and various processing steps. It should be appreciated that such block components may be realized by any number of hardware, software, and/or firmware components configured to perform the specified functions. For example, an embodiment of the present disclosure may employ various integrated circuit components, e.g., memory elements, digital signal processing elements, logic elements, look-up tables, or the like, which may carry out a variety of functions under the control of one or more microprocessors or other control devices. In addition, those skilled in the art will appreciate that embodiments of the present disclosure may be practiced in conjunction with any number of systems, and that the systems described herein is merely exemplary embodiments of the present disclosure.

For the sake of brevity, conventional techniques related to signal processing, data transmission, signaling, control, and other functional aspects of the systems (and the individual operating components of the systems) may not be described in detail herein. Furthermore, the connecting lines shown in the various figures contained herein are intended to represent example functional relationships and/or physical couplings between the various elements. It should be noted that many alternative or additional functional relationships or physical connections may be present in an embodiment of the present disclosure.

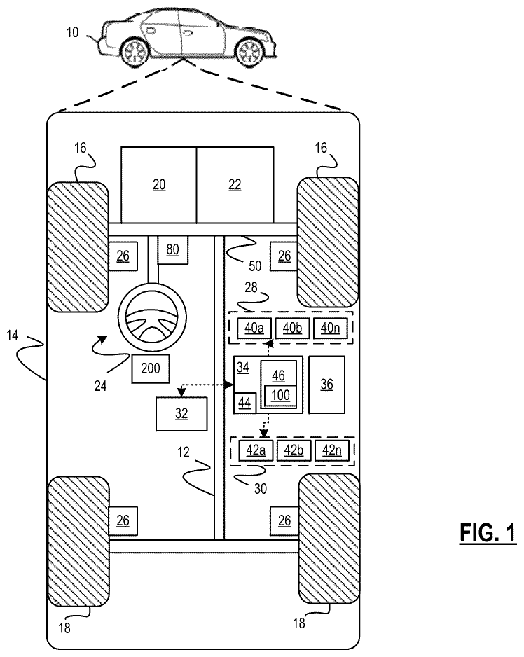

Referring to FIG. 1, a functional block diagram of a vehicle 10 including an energy management system 100 in accordance with at least one embodiment is shown. The vehicle 10 generally includes a chassis 12, a body 14, front wheels 16, and rear wheels 18. While the vehicle 10 is depicted in the illustrated embodiment as a passenger car, the vehicle 10 may be other types of vehicles including trucks, sport utility vehicles (SUVs), and recreational vehicles (RVs).

In various embodiments, the body 14 is arranged on the chassis 12 and substantially encloses components of the vehicle 10. The body 14 and the chassis 12 may jointly form a frame. The wheels 16, 18 are each rotationally coupled to the chassis 12 near a respective corner of the body 14.

In various embodiments, the vehicle 10 is an autonomous or semi-autonomous vehicle that is automatically controlled to carry passengers and/or cargo from one place to another. For example, in an exemplary embodiment, the vehicle 10 is a so-called Level Two, Level Three, Level Four or Level Five automation system. Level two automation means the vehicle assists the driver in various driving tasks with driver supervision. Level three automation means the vehicle can take over all driving functions under certain circumstances. All major functions are automated, including braking, steering, and acceleration. At this level, the driver can fully disengage until the vehicle tells the driver otherwise. A Level Four system indicates “high automation”, referring to the driving mode-specific performance by an automated driving system of all aspects of the dynamic driving task, even if a human driver does not respond appropriately to a request to intervene. A Level Five system indicates “full automation”, referring to the full-time performance by an automated driving system of all aspects of the dynamic driving task under all roadway and environmental conditions that can be managed by a human driver.

As shown, the vehicle 10 generally includes a propulsion system 20 a transmission system 22, a steering system 24, a braking system 26, a sensor system 28, an actuator system 30, at least one data storage device 32, at least one controller 34, and a communication system 36. The controller 34 is configured to implement an automated driving system (ADS). The propulsion system 20 is configured to generate power to propel the vehicle. In at least one embodiment, the propulsion system 20 includes an internal combustion engine (ICE). The propulsion system 20, in various embodiments, includes an electric machine such as a traction motor, a fuel cell propulsion system, and/or any other type of propulsion configuration. The transmission system 22 is configured to transmit power from the propulsion system 20 to the vehicle wheels 16, 18 according to selectable speed ratios. According to various embodiments, the transmission system 22 may include a step-ratio automatic transmission, a continuously-variable transmission, or other appropriate transmission. The braking system 26 is configured to provide braking torque to the vehicle wheels 16, 18. The braking system 26 may, in various embodiments, include friction brakes, brake by wire, a regenerative braking system such as an electric machine, and/or other appropriate braking systems.

The steering system 24 is configured to influence a position of the of the vehicle wheels 16. While depicted as including a steering wheel and steering column, for illustrative purposes, in some embodiments contemplated within the scope of the present disclosure, the steering system 24 may not include a steering wheel and/or steering column. The steering system 24 includes a steering column coupled to an axle 50 associated with the front wheels 16 through, for example, a rack and pinion or other mechanism (not shown). Alternatively, the steering system 24 may include a steer by wire system that includes actuators associated with each of the front wheels 16.

The sensor system 28 includes one or more sensing devices 40a-40n that sense observable conditions of the exterior environment and/or the interior environment of the vehicle 10. The sensing devices 40a-40n can include, but are not limited to, radars, lidars, global positioning systems, optical cameras, thermal cameras, ultrasonic sensors, a steering wheel sensor, and/or other sensors.

The vehicle dynamics sensors provide vehicle dynamics data including longitudinal speed, yaw rate, lateral acceleration, longitudinal acceleration, etc. The vehicle dynamics sensors may include wheel sensors that measure information pertaining to one or more wheels of the vehicle 10. In one embodiment, the wheel sensors comprise wheel speed sensors that are coupled to each of the wheels 16, 18 of the vehicle 10. Further, the vehicle dynamics sensors may include one or more accelerometers (provided as part of an Inertial Measurement Unit (IMU)) that measure information pertaining to an acceleration of the vehicle 10. In various embodiments, the accelerometers measure one or more acceleration values for the vehicle 10, including latitudinal and longitudinal acceleration and yaw rate. In at least one embodiment, the vehicle dynamic sensors provide vehicle location and vehicle movement data.

The actuator system 30 includes one or more actuator devices 42a-42n that control one or more vehicle features such as, but not limited to, one or more vehicle wheels 16, 18 the propulsion system 20, the transmission system 22, the steering system 24, and the braking system 26. In various embodiments, the vehicle features can further include interior and/or exterior vehicle features such as, but are not limited to, doors, a trunk, and cabin features such as air, music, lighting, etc. (not numbered).

The communication system 36 is configured to wirelessly communicate information to and from other entities 48, such as but not limited to, other vehicles (vehicle to vehicle, “V2V” communication,) infrastructure (vehicle to infrastructure “V2I” communication), remote systems, and/or personal devices. In an exemplary embodiment, the communication system 36 is a wireless communication system configured to communicate via a wireless local area network (WLAN) using IEEE 802.11 standards or by using cellular data communication. However, additional, or alternate communication methods, such as a dedicated short-range communications (DSRC) channel, are also considered within the scope of the present disclosure. DSRC channels refer to one-way or two-way short-range to medium-range wireless communication channels specifically designed for automotive use and a corresponding set of protocols and standards.

The data storage device 32 stores data for use in the ADS of the vehicle 10. In various embodiments, the data storage device 32 stores defined maps of the navigable environment. In various embodiments, the defined maps may be predefined by and obtained from a remote system. For example, the defined maps may be assembled by the remote system and communicated to the vehicle 10 (wirelessly and/or in a wired manner) and stored in the data storage device 32. As can be appreciated, the data storage device 32 may be part of the controller 34, separate from the controller 34, or part of the controller 34 and part of a separate system.

The controller 34 includes at least one processor 44 and a computer readable storage device or media 46. The processor 44 can be any custom made or commercially available processor, a central processing unit (CPU), a graphics processing unit (GPU), an auxiliary processor among several processors associated with the controller 34, a semiconductor-based microprocessor (in the form of a microchip or chip set), a macroprocessor, any combination thereof, or generally any device for executing instructions. The computer readable storage device or media 46 may include volatile and nonvolatile storage in read-only memory (ROM), random-access memory (RAM), and keep-alive memory (KAM), for example. KAM is a persistent or non-volatile memory that may be used to store various operating variables while the processor 44 is powered down. The computer-readable storage device or media 46 may be implemented using any of a number of known memory devices such as PROMs (programmable read-only memory), EPROMs (electrically PROM), EEPROMs (electrically erasable PROM), flash memory, or any other electric, magnetic, optical, or combination memory devices capable of storing data, some of which represent executable instructions, used by the controller 34 in controlling the vehicle 10. In at least one embodiment, the computer-readable storage device 46 is at least one memory configured to store the energy management system 100.

The instructions may include one or more separate programs, each of which comprises an ordered listing of executable instructions for implementing logical functions. The instructions, when executed by the processor 44, receive and process signals from the sensor system 28, perform logic, calculations, methods and/or algorithms for automatically controlling the components of the vehicle 10, and generate control signals to the actuator system 30 to automatically control the components of the vehicle 10 based on the logic, calculations, methods, and/or algorithms. Although only one controller 34 is shown in FIG. 1, embodiments of the vehicle 10 can include any number of controllers 34 that communicate over any suitable communication medium or a combination of communication mediums and that cooperate to process the sensor signals, perform logic, calculations, methods, and/or algorithms, and generate control signals to automatically control features of the vehicle 10. In various embodiments, the controller(s) 34 are configured to implement ADS.

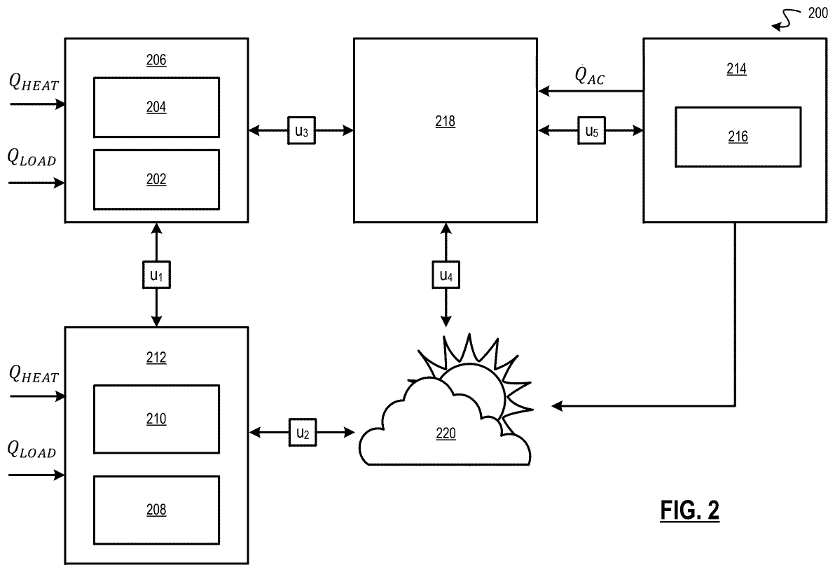

Referring to FIG. 2, a functional block diagram of a system 200 configured to implement an energy management system 100 in accordance with at least one embodiment is shown. The system 200 includes a high voltage (HV) battery 202, battery temperature sensor(s) 204, battery coolant 206, power electronics 208, power electronics temperature sensor(s) 210, power electronics coolant 212, a vehicle cabin 214, cabin temperatures sensor(s) 216, refrigerant 218, a first valve u₁, a second valve u₂, a third valve u₃, a fourth valve u₄, and a fifth valve u₅.

The battery temperature sensor(s) 204 is configured to sense a battery temperature of the HV battery 202. The power electronics temperature sensor(s) 210 is configured to sense a power electronics temperature of the power electronics 208. The cabin temperature sensor(s) 216 is configured to sense a vehicle cabin temperature of the vehicle cabin 214.

The first valve u₁ can be placed in one of an open position and a closed position. When the first valve u₁ is placed in the closed position, the battery coolant 206 is separated from the power electronics coolant 212. When the first valve u₁ is placed in the open position, the battery coolant 206 combines with the power electronics coolant 212 to create a combined coolant.

The second valve u₂ can be placed in one of an open position and a closed position. When the second valve u₂ is placed in the open position and the first valve u₁ is placed in the closed position, heat dissipation from the power electronics coolant 212 to ambient air 220 outside the vehicle 10 is enabled. When the second valve u₂ is placed in the open position and the first valve u₁ is placed in the open position, heat dissipation from the combined coolant to the ambient air 220 outside the vehicle 10 is enabled.

When the second valve u₂ is placed in the closed position and the first valve u₁ is placed in the closed position, heat dissipation from the power electronics coolant 212 to the ambient air 220 outside the vehicle 10 is disabled. When the second valve u₂ is placed in the closed position and the first valve u₁ is placed in the open position, heat dissipation from the combined coolant to the ambient air 220 outside the vehicle 10 is disabled.

The third valve u₃ can be placed in one of an open position and a closed position. When the third valve u₃ is placed in the closed position and the first valve u₁ is placed in the closed position, heat transfer between the battery coolant 206 and the refrigerant 218 is disabled. When the third valve u₃ is placed in the closed position and the first valve u₁ is placed in the open position, heat transfer between the combined coolant and the refrigerant 218 is disabled.

When the third valve u₃ is placed in the open position and the first valve u₁ is placed in the closed position, heat transfer between the battery coolant 206 and the refrigerant 218 is enabled. When the third valve u₃ is placed in the open position and the first valve u₁ is placed in the open position, heat transfer between the combined coolant and the refrigerant 218 is enabled.

The fourth valve u₄ can be placed in one of an open position and a closed position. When the fourth valve u₄ is placed in the closed position, heat dissipation from the refrigerant 218 to the ambient air 220 outside the vehicle 10 is disabled. When the fourth valve u₄ is placed in the open position, heat dissipation from the refrigerant 218 to the ambient air 220 outside the vehicle 10 is enabled.

The fifth valve u₅ can be placed in one of an open position and a closed position. When the fifth valve u₅ is placed in the closed position, heat transfer between the air in the vehicle cabin 214 and the refrigerant 218 is disabled. When the fifth valve u₅ is placed in the open position, heat transfer between the air in the vehicle cabin 214 and the refrigerant 218 is enabled. Heat from the vehicle cabin 214 can also be dissipated to the ambient air 220 outside the vehicle.

The HV battery 202 is configured to supply heating power Q_{HEAT} to the battery coolant 206 and the power electronics coolant 212 when the first valve u₁ is closed. The HV battery 202 is configured to supply heating power Q_{HEAT} to the combined coolant when the first valve u₁ is open. The HV battery 202 is configured to supply cooling power Q_{AC} to the refrigerant.

When the first valve u₁ is closed and the third valve u₃ is closed, the battery temperature of the HV battery 202 is based on the battery coolant temperature of the battery coolant 206. The battery coolant temperature is based on an amount of load related heating power Q_{LOAD} resulting from a load on one or more components of the vehicle 10 applied to the battery coolant 206 and an amount of heating power Q_{HEAT} applied to the battery coolant 206 by the HV battery 202.

When the first valve u₁ is open and the third valve u₃ is closed, the battery temperature of the HV battery 202 is based on the combined coolant temperature of the combined coolant. The combined coolant temperature is based on an amount of load related heating power Q_{LOAD} resulting from a load on one or more components of the vehicle 10 applied to the combined coolant and an amount of heating power Q_{HEAT} applied to the combined coolant by the HV battery 202.

When the first valve u₁ is closed and the third valve u₃ is open, the battery temperature of the HV battery 202 is based on the battery coolant temperature of the battery coolant 206. The battery coolant temperature is based on the refrigerant temperature of the refrigerant 218, an amount of load related heating power Q_{LOAD} resulting from a load on one or more components of the vehicle 10 applied to the battery coolant 206 and an amount of heating power Q_{HEAT} applied to the battery coolant 206 by the HV battery 202.

When the first valve u₁ is open and the third valve u₃ is open, the battery temperature of the HV battery 202 is based on the combined coolant temperature of the combined coolant. The combined coolant temperature is based on the refrigerant temperature of the refrigerant 218, an amount of load related heating power Q_{LOAD} resulting from a load on one or more components of the vehicle 10 applied to the combined coolant, and an amount of heating power Q_{HEAT} applied to the combined coolant by the HV battery 202.

When the first valve u₁ is closed and the second valve u₂ is closed, the power electronics temperature of the power electronics 208 is based on the power electronics coolant temperature of the power electronics coolant 212. The power electronics coolant temperature is based on an amount of load related heating power Q_{LOAD} resulting from a load on one or more components of the vehicle 10 applied to the power electronics coolant 212 and an amount of heating power Q_{HEAT} applied to the power electronics coolant 212 by the HV battery 202. The amount of heating power Q_{HEAT} applied to the power electronics coolant 212 is the same as the heating power Q_{HEAT} applied to the battery coolant 206.

When the first valve u₁ is open and the second valve u₂ is closed, the power electronics temperature of the power electronics 208 is based on the combined coolant temperature of the combined coolant. The combined coolant temperature is based on an amount of load related heating power Q_{LOAD} resulting from a load on one or more components of the vehicle 10 applied to the combined coolant and an amount of heating power Q_{HEAT} applied to the combined coolant by the HV battery 202.

When the first valve u₁ is closed and the second valve u₂ is open, the power electronics temperature of the power electronics 208 is based on the power electronics coolant temperature of the power electronics coolant 212. The power electronics coolant temperature is based on an amount of load related heating power Q_{LOAD} resulting from a load on one or more components of the vehicle 10 applied to the power electronics coolant 212, an amount of heating power Q_{HEAT} applied to the power electronics coolant 212 by the HV battery 202, and an amount of heat dissipated from the power electronics coolant 212 to the ambient air 220 outside the vehicle 10.

When the first valve u₁ is open and the second valve u₂ is open, the power electronics temperature of the power electronics 208 is based on the combined coolant temperature of the combined coolant. The combined coolant temperature is based on an amount of load related heating power Q_{LOAD} resulting from a load on one or more components of the vehicle 10 applied to the combined coolant, an amount of heating power Q_{HEAT} applied to the combined coolant by the HV battery 202, and an amount of heat dissipated from the combined coolant to the ambient air 220 outside the vehicle 10.

The refrigerant temperature of the refrigerant 218 is based on the positions of the third valve u₃, the fourth valve u₄ and the fifth valve u₅. When the third valve u₃ is closed, the battery coolant temperature (if the first valve u₁ is closed) or the combined coolant temperatures (if the first valve u₁ is open) do not impact the refrigerant temperature. When the third valve u₃ is open, the battery coolant temperature (if the first valve u₁ is closed) or the combined coolant temperature (if the first valve u₁ is open) impact the refrigerant temperature.

When the fourth valve u₄ is closed, heat dissipation from the refrigerant to the ambient air outside the vehicle 10 is disabled. When the fourth valve u₄ is open, heat dissipation from the refrigerant to the ambient air outside the vehicle 10 is enabled impacting the refrigerant temperature.

When the fifth valve u₅ is open, heat exchange between the refrigerant and the air inside the vehicle cabin 214 is enabled thereby impacting the refrigerant temperature. When the fifth valve u₅ is closed, heat exchange between the refrigerant and the air inside the vehicle cabin 214 is disabled.

The HV battery is configured to apply an amount of cooling power Q_{AC} to the refrigerant 218. The refrigerant temperature is impacted by the amount of cooling power Q_{AC} applied to the refrigerant 218. The change in the refrigerant temperature associated with the application of the amount of cooling power Q_{AC} to the refrigerant 218 impacts one or more of the battery coolant temperature, the combined coolant temperature, and the vehicle cabin temperature based on the positions of the third valve u₃, the fourth valve u₄ and the fifth valve u₅.

When the fifth valve u₅ is placed in the closed position, the vehicle cabin temperature of the vehicle cabin 214 is not impacted by the temperature of the refrigerant 218. When the fifth valve u₅ is placed in the open position, heat exchange occurs between the air in the vehicle cabin and the refrigerant impacting the vehicle cabin temperature of the vehicle cabin 214. Heat from the vehicle cabin can be dissipated to the ambient air 220 outside the vehicle 10.

While the system 200 is shown as including five valves, in alternative embodiments, the system 20 may include a fewer or greater number of valves. The implementation of the energy management system 100 using the system 200 will be described in greater detail below.

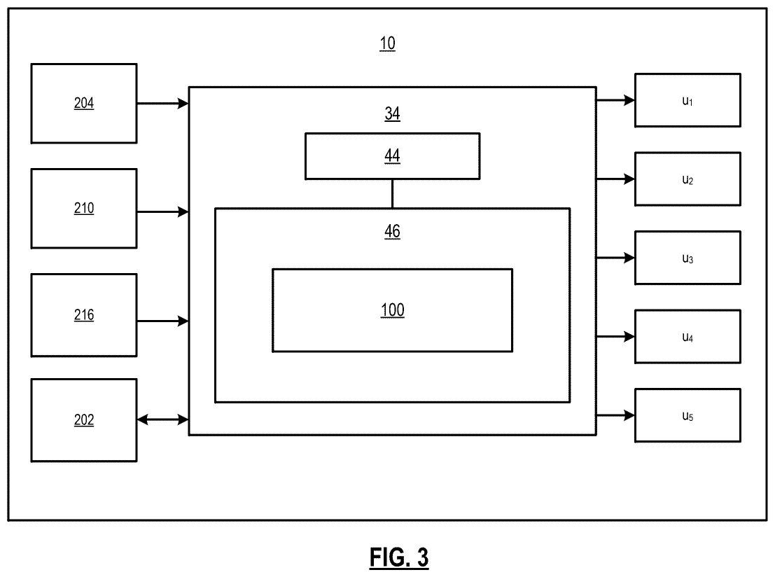

Referring to FIG. 3, a functional block diagram of a controller 34 including an energy management system 100 in accordance with at least one embodiment is shown. The controller 34 includes at least one processor 44 and at least one memory 46. The at least one processor 44 is a programable device that includes one or more instructions stored in or associated with the at least one memory 46. The at least one memory 46 includes instructions that the at least one processor 44 is configured to execute. The at least one memory 46 includes an embodiment of the energy management system 100.

The controller 34 is configured to be communicatively coupled to an HV battery 202, one or more battery temperature sensors 204, one more power electronics temperature sensors 210, one or more cabin temperature sensors 216, the first valve u₁, the second valve u₂, the third valve u₃, the fourth valve u₄, and the fifth valve u₅. The controller 34 may include additional components that facilitate operation of the energy management system 100. The operation of the energy management system 100 will be described in greater detail below. In at least one embodiment, the controller 34 may be referred to as the energy management system.

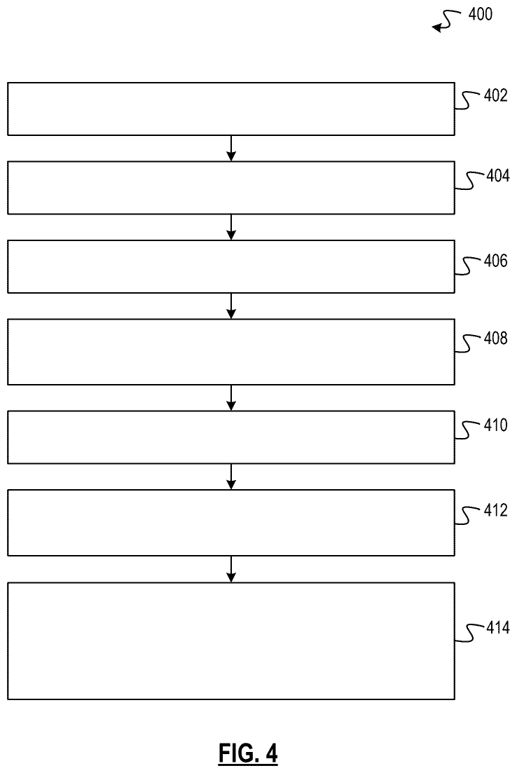

Referring to FIG. 4, a flowchart representation of an exemplary method 400 of managing energy in accordance with at least one embodiment is shown. The method 400 will be described with reference to an exemplary implementation of an embodiment of an energy management system 100. As can be appreciated in light of the disclosure, the order of operation within the method 400 is not limited to the sequential execution as illustrated in FIG. 4 but may be performed in one or more varying orders as applicable and in accordance with the present disclosure.

At 402, the energy management system 100 receives a battery temperature of a HV battery 202 from a battery temperature sensor(s) 204. At 404, the energy management system 100 receives a power electronics temperature of power electronics 208 from a power electronics temperature sensor(s) 210. At 406, the energy management system 100 receives a vehicle cabin temperature of a vehicle cabin 214 from a cabin temperature sensor(s) 216.

At 408, the energy management system 100 calculates a battery temperature difference between the battery temperature and a desired battery temperature, a power electronics temperature difference between the power electronics temperature and a desired power electronics temperature, and a cabin temperature difference between the vehicle cabin temperature and a desired vehicle cabin temperature. The desired battery temperature, the desired power electronics temperature, and the desired vehicle cabin temperature are pre-defined values that are stored at the energy management system 100.

At 410, the energy management system 100 determines a power tuning factor γ. The power tuning factor Y defines an amount of power including an amount of heating power Q_{HEAT} and an amount of cooling power Q_{AC} that will be used to significantly reduce or eliminate the battery temperature difference, the power electronics temperature difference, and the cabin temperature difference. The higher the value of the power tuning factor Y, the higher the amount of power including the amount of heating power Q_{HEAT} and the amount of cooling power Q_{AC} that will be used to significantly reduce or eliminate the battery temperature difference, the power electronics temperature difference, and the cabin temperature difference.

The amount of heating power Q_{HEAT} is used to heat either the battery coolant 206 and the power electronics coolant 212 or a combined coolant based on whether the first valve u₁ has been placed in an open position of an open position. The combined coolant is a combination of the battery coolant 206 and the power electronics coolant 212. The amount of the cooling power Q_{AC} is used to cool the refrigerant 218.

A cost function J1 defines the relationship between the battery temperature, the desired battery temperature, the power electronics temperature, the desired power electronics temperature, the amount of the heating power, the amount of the cooling power, and the power tuning factor γ. The cost function J1 is shown below:

$$J 1 = {\sum }_{k = 1}^{N} ( {( {T}_{b} ( k ) - {T}_{b}^{des} )}^{2} + {( {T}_{p} ( k ) - {T}_{p}^{des} )}^{2} + {( {T}_{c} ( k ) - {T}_{c}^{des} )}^{2} + \text{?} ( {Q}_{HEAT}^{2} ( k ) + {Q}_{AC}^{2} ( k ) ) ,$$

wherein: T_{b} is the battery temperature,

$${T}_{b}^{des}$$

is the desire battery temperature, Tₚ is the power electronics temperature,

$${T}_{p}^{des}$$

is the desired power electronics temperature, Q_{HEAT} is the amount of the heating power, Q_{AC} is the amount of the cooling power, γ is the power tuning factor, and k is time steps/through N. The value of the amount of the heating power Q_{HEAT} is greater than or equal to zero. The value of the amount of the cooling power Q_{AC} is greater than or equal to zero.

In at least one embodiment, the energy management system 100 receives a state of charge (SOC) of the HV battery 202 from the HV battery 202. The HV battery 202 supplies the amount of cooling power Q_{AC} and the amount of heating power Q_{HEAT} associated with the power tuning factor γ. The energy management system 100 determines the power tuning factor Y based on the SOC of the HV battery 202. For example, when the SOC of the HV battery 202 has a first SOC value, the energy management system 100 determines a first power tuning factor Y and when the SOC of the HV battery 202 has a second SOC value, the energy management system 100 determines a second power tuning factor γ. The first SOC value is higher than the second SOC value. The first power tuning factor Y based on the first SOC value is higher than the second power tuning factor Y based on the second SOC value. The higher the power tuning factor Y the higher the amount of cooling power Q_{AC} and the amount of heating power Q_{HEAT} that will be used to heat/cool the refrigerant/coolants.

At 412, the energy management system 100 places each of a plurality of valves u₁, u₂, u₃, u₄, u₅ in one of an open position and a closed position. The energy management system 100 identifies the valves from the plurality of valves u₁, u₂, u₃, u₄, u₅ to place in the open position and the valves from the plurality of valves u₁, u₂, u₃, u₄, u₅ to place in the close position in order to achieve a significant reduction in or the elimination of the battery temperature difference, the power electronics temperature difference, and the cabin temperature difference using the amount of cooling power Q_{AC} and the amount of heating power Q_{HEAT} associated with the power tuning factor Y in the shortest amount of time possible.

At 414, the amount of the heating power and the amount of the cooling power is applied to significantly reduce or eliminate the battery temperature difference, the power electronics temperature difference and the cabin temperature difference.

In at least one embodiment, the cost function J2 defines the relationship between the battery temperature, the desired battery temperature, the power electronics temperature, the desired power electronics temperature, the amount of the heating power, the amount of the cooling power, and the power tuning factor γ. The cost function J2 is shown below:

$$J 2 = {\sum }_{k = 1}^{N} ( {{W}_{b} ( {T}_{b} ( k ) - {T}_{b}^{des} )}^{2} + {{W}_{p} ( {T}_{p} ( k ) - {T}_{p}^{des} )}^{2} + {{W}_{c} ( {T}_{c} ( k ) - {T}_{c}^{des} )}^{2} + γ ( {Q}_{HEAT}^{2} ( k ) + {Q}_{AC}^{2} ( k ) ) ,$$

wherein: T_{b} is the battery temperature,

$${T}_{b}^{des}$$

is the desire battery temperature, Tₚ is the power electronics,

$${T}_{p}^{des}$$

is the desired power electronics temperature, Q_{HEAT} is the power electronics temperature, amount of the heating power, Q_{AC} is the amount of the cooling power, γ is the power tuning factor, W_{b} is a battery temperature weighting factor, Wₚ is a power electronics temperature weighting factor, W_{c} is a cabin temperature weighting factor, and k is time steps/through N.

The use of the battery temperature weighting factor W_{b}, the power electronics temperature weighting factor Wₚ and the cabin temperature weighting factor W_{c}, defines the allocation of the amount of the heating power Q_{HEAT} and the allocation the amount of the cooling power Q_{AC} and prioritizes an achievement in a significant reduction or an of elimination of each of the battery temperature difference, the power electronics temperature difference, and the cabin temperature difference with respect to each other.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing the exemplary embodiment or exemplary embodiments. It should be understood that various changes can be made in the function and arrangement of elements without departing from the scope of the disclosure as set forth in the appended claims and the legal equivalents thereof.

What is claimed is:

1. An energy management system for a vehicle, comprising:
at least one processor; and
at least one memory communicatively coupled to the at least one processor, the at least one memory comprising instructions that upon execution by the at least one processor, causes the at least one processor to:
receive a battery temperature from a battery temperature sensor of a high voltage (HV) battery of the vehicle, the battery temperature of the HV battery being based a battery coolant temperature of a battery coolant;
receive a power electronics temperature from a power electronics temperature sensor of power electronics of the vehicle, the power electronics temperature being based on a power electronics coolant temperature of a power electronics coolant;
receive a vehicle cabin temperature from a cabin temperature sensor of a vehicle cabin, the vehicle cabin temperature being based on a refrigerant temperature of a refrigerant;
calculate a battery temperature difference between the battery temperature and a desired battery temperature, a power electronics temperature difference between the power electronics temperature and a desired power electronics temperature, and a cabin temperature difference between the vehicle cabin temperature and a desired vehicle cabin temperature;
generate a power tuning factor to determine an amount of cooling power to apply to the refrigerant and an amount of heating power to apply to the battery coolant and the power electronics coolant; and
place each of a plurality of valves in one of an open position and a closed position to enable heat exchange between one or more of the battery coolant, the power electronics coolant, the refrigerant, and ambient air outside the vehicle to eliminate the battery temperature difference, the power electronics temperature difference, and the cabin temperature difference using the amount of cooling power and the amount of heating power associated with the power tuning factor.

2. The system of claim 1, wherein the at least one memory further comprises instructions that upon execution by the at least one processor, causes the at least one processor to place a first valve of the plurality of valves in one of an open position and a closed position, wherein:
the open position of the first valve merges the battery coolant with the power electronics coolant to generate a combined coolant,
the battery temperature of the HV battery and the power electronics temperature of the power electronics is based on a combined coolant temperature of the combined coolant, and
the closed position of the first valve separates the battery coolant from the power electronics coolant.

3. The system of claim 2, wherein the at least one memory further comprises instructions that upon execution by the at least one processor, causes the at least one processor to place a second valve of the plurality of valves in one of an open position and a closed position, wherein:
the open position of the second valve enables dissipation of heat from one of the power electronics coolant and the combined coolant to the ambient air outside of the vehicle, and
the closed position of the second valve disables the dissipation of heat from the one of the power electronics coolant and the combined coolant to the ambient air.

4. The system of claim 2, wherein the at least one memory further comprises instructions that upon execution by the at least one processor, causes the at least one processor to place a third valve of the plurality of valves in one of an open position and a closed position, wherein:
the open position of the third valve enables heat transfer between the refrigerant and one of the battery coolant and the combined coolant, and
the closed position disables the heat transfer between the refrigerant and the one of the battery coolant and the combined coolant.

5. The system of claim 1, wherein the at least one memory further comprises instructions that upon execution by the at least one processor, causes the at least one processor to place a fourth valve of the plurality of valves in one of an open position and a closed position, wherein:
the open position of the fourth valve enables dissipation of heat from the refrigerant to the ambient air outside of the vehicle, and
the closed position disables the dissipation of heat from the refrigerant to the ambient air.

6. The system of claim 1, wherein the at least one memory further comprises instructions that upon execution by the at least one processor, causes the at least one processor to place a fifth valve of the plurality of valves in one of an open position and a closed position, wherein:
the open position of the fifth valve enables heat exchange between the air in the vehicle cabin and the refrigerant, and
the closed position disables the heat exchange between the air in the vehicle cabin and the refrigerant.

7. The system of claim 1, wherein the at least one memory further comprises instructions that upon execution by the at least one processor, causes the at least one processor to apply the amount of the heating power and the amount of the cooling power in accordance with the generated power tuning factor based on a relationship defined by a first cost function J1, the first cost function J1 being:
$$J 1 = {\sum }_{k = 1}^{N} ( {( {T}_{b} ( k ) - {T}_{b}^{des} )}^{2} + {( {T}_{p} ( k ) - {T}_{p}^{des} )}^{2} + {( {T}_{c} ( k ) - {T}_{c}^{des} )}^{2} + γ ( {Q}_{HEAT}^{2} ( k ) + {Q}_{AC}^{2} ( k ) ) ,$$
wherein: T_{b} is the battery temperature,
$${T}_{b}^{des}$$
is the desired battery temperature temperature, Tₚ is the power electronics temperature,
$${T}_{p}^{des}$$
is the desired power electronics temperature, Q_{HEAT} is the amount of the heating power, Q_{AC} is the amount of the cooling power, γ is the power tuning factor, and k is time steps 1 through N.

8. The system of claim 7, wherein the amount of the heating power is greater than or equal zero and the amount of the cooling power is greater than or equal zero.

9. The system of claim 1, wherein the at least one memory further comprises instructions that upon execution by the at least one processor, causes the at least one processor to apply the amount of the heating power and the amount of the cooling power in accordance with the generated power tuning factor based on a relationship defined by a second cost function J2, the cost function J2 being:
$$J 2 = {\sum }_{k = 1}^{N} ( {{W}_{b} ( {T}_{b} ( k ) - {T}_{b}^{des} )}^{2} + {{W}_{p} ( {T}_{p} ( k ) - {T}_{p}^{des} )}^{2} + {{W}_{c} ( {T}_{c} ( k ) - {T}_{c}^{des} )}^{2} + γ ( {Q}_{HEAT}^{2} ( k ) + {Q}_{AC}^{2} ( k ) ) ,$$
wherein: T_{b} is the battery temperature,
$${T}_{b}^{des}$$
is the desire battery temperature, Tₚ is the power electronics temperature,
$${T}_{p}^{des}$$
is the desired power electronics temperature, Q_{HEAT} is the amount of the heating power, Q_{AC} is the amount of the cooling power, γ is the power tuning factor, W_{b} is a battery temperature weighting factor, Wₚ is a power electronics temperature weighting factor, W_{c} is a cabin temperature weighting factor, and k is time steps 1 through N.

10. The system of claim 1, wherein the at least one memory further comprises instructions that upon execution by the at least one processor, causes the at least one processor to:
receive a state of charge (SOC) of the HV battery; and
generate the power tuning factor based on the SOC of the HV battery.

11. A method of managing energy in a vehicle comprising:
receiving, by the controller, a battery temperature from a battery temperature sensor of a high voltage (HV) battery of the vehicle, the battery temperature of the HV battery being based a battery coolant temperature of a battery coolant;
receiving, by the controller, a power electronics temperature from a power electronics temperature sensor of power electronics of the vehicle, the power electronics temperature being based on a power electronics coolant temperature of a power electronics coolant;
receiving, by the controller, a vehicle cabin temperature from a cabin temperature sensor of a vehicle cabin, the vehicle cabin temperature being based on a refrigerant temperature of a refrigerant;
calculating, by the controller, a battery temperature difference between the battery temperature and a desired battery temperature, a power electronics temperature difference between the power electronics temperature and a desired power electronics temperature, and a cabin temperature difference between the vehicle cabin temperature and a desired vehicle cabin temperature;
generating, by the controller, a power tuning factor to determine an amount of cooling power to apply to the refrigerant and an amount of heating power to apply to the battery coolant and the power electronics coolant; and
placing, by the controller, each of a plurality of valves in one of an open position and a closed position to enable heat exchange between one or more of the battery coolant, the power electronics coolant, the refrigerant, and ambient air outside the vehicle to eliminate the battery temperature difference, the power electronics temperature difference, and the cabin temperature difference using the amount of cooling power and the amount of heating power associated with the power tuning factor.

12. The method of claim 11, further comprising placing, by the controller, a first valve of the plurality of valves in one of an open position and a closed position, wherein:
the open position of the first valve merges the battery coolant with the power electronics coolant to generate a combined coolant,
the battery temperature of the HV battery and the power electronics temperature of the power electronics is based on a combined coolant temperature of the combined coolant, and
the closed position of the first valve separates the battery coolant from the power electronics coolant.

13. The method of claim 12, further comprising placing, by the controller, a second valve of the plurality of valves in one of an open position and a closed position, wherein:
the open position of the second valve enables dissipation of heat from one of the power electronics coolant and the combined coolant to the ambient air outside of the vehicle, and
the closed position of the second valve disables the dissipation of heat from the one of the power electronics coolant and the combined coolant to the ambient air.

14. The method of claim 12, further comprising placing, by the controller, a third valve of the plurality of valves in one of an open position and a closed position, wherein:
the open position of the third valve enables heat transfer between the refrigerant and one of the battery coolant and the combined coolant, and
the closed position disables the heat transfer between the refrigerant and the one of the battery coolant and the combined coolant.

15. The method of claim 11, further comprising placing, by the controller, a fourth valve of the plurality of valves in one of an open position and a closed position, wherein:
the open position of the fourth valve enables dissipation of heat from the refrigerant to the ambient air outside of the vehicle, and
the closed position disables the dissipation of heat from the refrigerant to the ambient air.

16. The method of claim 11, further comprising placing, by the controller, a fifth valve of the plurality of valves in one of an open position and a closed position, wherein:
the open position of the fifth valve enables heat exchange between the air in the vehicle cabin and the refrigerant, and
the closed position disables the heat exchange between the air in the vehicle cabin and the refrigerant.

17. The method of claim 11, further comprising applying the amount of the heating power and the amount of the cooling power in accordance with the generated power tuning factor based on a relationship defined by a first cost function J1, the first cost function J1 being:
$$J 1 = {\sum }_{k = 1}^{N} ( {( {T}_{b} ( k ) - {T}_{b}^{des} )}^{2} + {( {T}_{p} ( k ) - {T}_{p}^{des} )}^{2} + {( {T}_{c} ( k ) - {T}_{c}^{des} )}^{2} + γ ( {Q}_{HEAT}^{2} ( k ) + {Q}_{AC}^{2} ( k ) ) ,$$
wherein: T_{b} is the battery temperature,
$${T}_{b}^{des}$$
is the desire battery temperature, Tₚ is the power electronics temperature,
$${T}_{p}^{des}$$
is the desired power electronics temperature, Q_{HEAT} is the amount of the heating power, Q_{AC} is the amount of the cooling power, γ is the power tuning factor, and k is time steps 1 through N.

18. The method of claim 11, further comprising applying the amount of the heating power and the amount of the cooling power in accordance with the generated power tuning factor based on a relationship defined by a second cost function J2, the cost function J2 being:
$$J 2 = {\sum }_{k = 1}^{N} ( {{W}_{b} ( {T}_{b} ( k ) - {T}_{b}^{des} )}^{2} + {{W}_{p} ( {T}_{p} ( k ) - {T}_{p}^{des} )}^{2} + {{W}_{c} ( {T}_{c} ( k ) - {T}_{c}^{des} )}^{2} + γ ( {Q}_{HEAT}^{2} ( k ) + {Q}_{AC}^{2} ( k ) ) ,$$
wherein: T_{b} is the battery temperature,
$${T}_{b}^{des}$$
is the desire battery temperature, Tₚ is the power electronics temperature,
$${T}_{p}^{des}$$
is the desired power electronics temperature, Q_{HEAT} is the amount of the heating power, Q_{AC} is the amount of the cooling power, γ is the power tuning factor, W_{b} is a battery temperature weighting factor, Wₚ is a power electronics temperature weighting factor, W_{c} is a cabin temperature weighting factor, and k is time steps/through N.

19. The method of claim 11, further comprising:
receiving a state of charge (SOC) of the HV battery; and
generating the power tuning factor based on the SOC of the HV battery.

20. A vehicle including an energy management system comprising:
at least one processor; and
at least one memory communicatively coupled to the at least one processor, the at least one memory comprising instructions that upon execution by the at least one processor, causes the at least one processor to:
at least one processor; and
at least one memory communicatively coupled to the at least one processor, the at least one memory comprising instructions that upon execution by the at least one processor, causes the at least one processor to:
receive a battery temperature from a battery temperature sensor of a high voltage (HV) battery of the vehicle, the battery temperature of the HV battery being based a battery coolant temperature of a battery coolant;
receive a power electronics temperature from a power electronics temperature sensor of power electronics of the vehicle, the power electronics temperature being based on a power electronics coolant temperature of a power electronics coolant;
receive a vehicle cabin temperature from a cabin temperature sensor of a vehicle cabin, the vehicle cabin temperature being based on a refrigerant temperature of a refrigerant;
calculate a battery temperature difference between the battery temperature and a desired battery temperature, a power electronics temperature difference between the power electronics temperature and a desired power electronics temperature, and a cabin temperature difference between the vehicle cabin temperature and a desired vehicle cabin temperature;
generate a power tuning factor to determine an amount of cooling power to apply to the refrigerant and an amount of heating power to apply to the battery coolant and the power electronics coolant; and
place each of a plurality of valves in one of an open position and a closed position to enable heat exchange between one or more of the battery coolant, the power electronics coolant, the refrigerant, and ambient air outside the vehicle to eliminate the battery temperature difference, the power electronics temperature difference, and the cabin temperature difference using the amount of cooling power and the amount of heating power associated with the power tuning factor.
